(19) United States
(12) Patent Application Publication
(10) Pub. No.: US 2015/0296660 A1
(43) Pub. Date: Oct. 15, 2015

(54) Device for Cooling Power Electronics by Means of a Cooling Medium and Method for Producing the Device

(71) Applicant: Hella KGaA Hueck & Co., Lippstadt (DE)

(72) Inventor: Frank Ströwer, Mohnesee (DE)

(21) Appl. No.: 14/685,057

(22) Filed: Apr. 13, 2015

(30) Foreign Application Priority Data
Apr. 14, 2014 (DE) 102014105269.2

(51) Int. Cl. H05K 7/20; B23P 15/26

(52) U.S. Cl. CPC H05K 7/20254; B23P 15/26

(57) ABSTRACT

A device for cooling power electronics by means of a cooling medium. The power electronics are arranged in a housing.

### CROSS REFERENCE

This application claims priority to German Application No. 10 2014 105269.2, filed Apr. 14, 2014, which is hereby incorporated by reference.

### FIELD OF TECHNOLOGY

The invention relates to a device for cooling power electronics by means of a cooling medium and a method for producing the device.

### BACKGROUND

Water cooling systems for power electronics are known from prior art. For these water cooling systems, housings are produced by means of die-casting, a production method that is relatively expensive. The use of die-cast housings is accompanied by relatively high power losses. Other well-known housings are made of sheet metal, which have to be subjected to a complicated soldering process in order to obtain a tight enclosure.

### SUMMARY OF THE INVENTION

It is the object of the invention to overcome the disadvantages encountered in prior art and to provide a device for cooling power electronic which can be produced in a cost-effective manner, and to provide a method for producing the device in order to manufacture the device in a simple manner.

To solve this problem, a device for cooling power electronics by means of a cooling medium is provided, wherein the power electronics are arranged in a housing and wherein the device has a housing attachment arranged at the housing in such a way that the housing attachment and the housing form a space for receiving the cooling medium, characterized in that the housing has at least a bottom part and a top part, wherein both housing parts are arranged to be connected by means of a laser welding process, wherein the housing attachment and the housing are arranged to be connected by means of a laser welding process, and wherein the housing and the housing attachment are made out of aluminum.

The invention has the special advantage that because of the provision of the housing attachment, which is arranged directly at the housing, power losses can be dissipated through forced convection by means of the cooling medium.

Because of the fact that the housing consists of a bottom part and a top part, it is easy to assemble the housing.

Using aluminum has the advantage that the device has low weight. Furthermore, it is possible to interconnect by means of the laser welding process the components bottom part and top part of the housing, as well as top part of the housing and housing attachment. Moreover, aluminum has high corrosive resistance.

Preferably, the power electronics indicate a subfield of electrical technology, which has the purpose of transforming electric power by means of electronic components. Typical uses are converters and frequency converters in the field of electric propulsion technology.

It is preferred when the power electronics are motor vehicle power electronics.

It is especially preferred when the power electronics are used for DC/DC converters (=direct current converter) for supplying an electrical supply system from a battery.

Preferably, the cooling medium involves water, air, alcohols, ois or a mixture thereof.

Preferably, the cooling medium involves a cooling agent. It is especially preferred when the cooling process is performed by means of a water/glycol mixture.

It is preferred when the space is designed in the form of a cooling medium container.

It is especially preferred when the housing attachment can be connected with the top part and/or the bottom part of the housing.

According to a further development of the invention, the housing and housing attachment consist of an aluminum alloy or 99.5% aluminum.

As a result, the bottom part and top part of the housing, as well as the housing attachment can be connected in a quick manner by means of the laser welding process.

Preferably, the housing and housing attachment consist of a brass alloy or brass.

Preferably, the housing has an airtight or watertight design.

According to a further development of the invention, the bottom part and the top part of the housing are deep-drawn, punched or deep-pressed.

In this way, it is possible to use simple forming processes for producing the bottom part and top part of the housing.

According to a further development of the invention, the bottom part and the top part of the housing have a brim, wherein the connection between the two housing parts takes place via the brims.

Both housing parts can be connected via the brims by means of the laser welding process.

Preferably, each brim is designed in the form of an edge or fold.

During the laser welding process, one of the brims melts in such a way that a firm connection is formed between the bottom part and the top part of the housing.

As a result, it is possible to achieve a firm connection between the bottom part and the top part of the housing.

According to a further development of the invention, the bottom part and the top part of the housing are deep-drawn, punched or deep-pressed.

In this way, it is possible to use a simple forming process for producing the housing attachment.

According to a further development of the invention, the housing attachment has a brim, wherein the housing attachment can be connected to the housing by means of the brim.

Preferably, the brim is designed in the form of an edge or fold.

During the laser welding process, the brim melts in such a way that a firm connection is formed to the housing.

As a result, it is possible to achieve a firm connection between the housing attachment and the housing.

Preferably, the housing attachment and the housing form a further housing which surrounds the space for receiving the cooling medium.

According to a further development of the invention, the housing attachment has at least one inlet and at least one outlet for the cooling medium.

In this way, the cooling medium can flow from the inlet via the space formed by the first housing and the housing attachment to the outlet and carry away heat.

According to a further development of the invention, the inlet and outlet can be connected to recesses of the housing attachment by means of a laser welding process.

In this way, it is possible to form a simple connection.

In order to solve the problem a method for producing a device for cooling the power electronics has been provided, which comprises the following steps:
Connecting by means of a laser welding process a bottom part and a top part of a housing to form a housing, wherein the power electronics are arranged in the housing, and
Connecting by means of a laser welding process the housing with a housing attachment, wherein the housing attachment and the housing form a space for receiving a cooling medium and wherein the housing and the housing attachment consist of aluminum.

Preferably, the top part of the housing is connected with the housing attachment.

In order to solve the problem a further method for producing a device for cooling the power electronics has been provided, which comprises the following steps:
Connecting by means of a laser welding process a top part of the housing with a housing attachment, wherein the housing attachment and the top part of the housing form a space for receiving a cooling medium, and
Connecting by means of a laser welding process a bottom part and top part of the housing to form a housing, wherein the power electronics are arranged in the housing, and wherein the housing and the housing attachment consist of aluminum.

Preferably, the space for receiving the cooling medium is arranged outside the housing. Preferably, the housing attachment and the housing form an additional housing, which surrounds the space for receiving the cooling medium.

Preferably, at least one inlet and one outlet are provided at recesses of the housing attachment to carry the cooling medium into and out of the space.

Preferably, the inlet and outlet are designed in the form of connection pieces.

It is especially preferred when the inlet and the outlet are connected by means of a laser welding process.

Preferably, the brim of the top part of the housing and the brim of the housing attachment has a bending angle that is larger than 90°, especially preferred 92°. As a result, the brims are not left hanging in the air.

According to a further development of the invention, the laser welding process is performed with a speed of 10 to 30 m/min.

In this way, all component of the device can be connected in a quick manner.

### BRIEF DESCRIPTION OF THE DRAWINGS

Reference is now made more particularly to the drawings, which illustrate the best presently known mode of carrying out the invention and wherein similar reference characters indicate the same parts throughout the views.

FIG. 1 is a schematic view on the invention-based device.

FIG. 2 is a schematic partial view of section A-A through the invention-based device shown in FIG. 1.

### DETAILED DESCRIPTION OF THE DRAWINGS

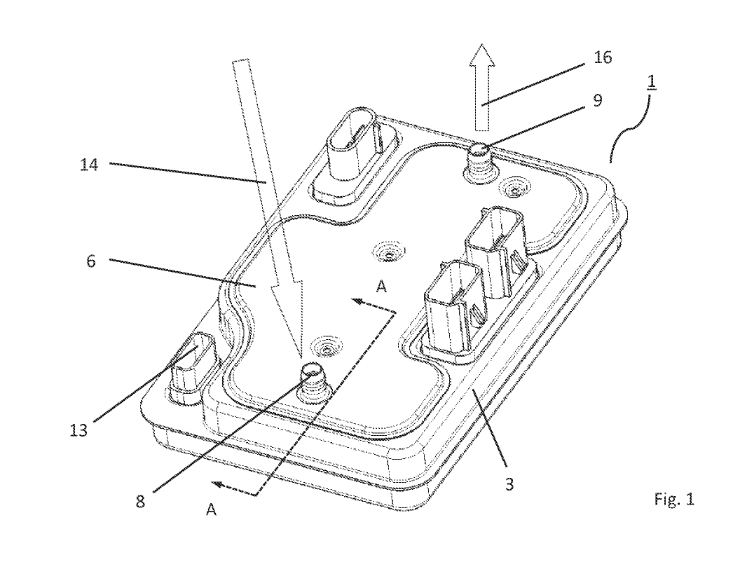

FIG. 1 shows a perspective schematic view on the invention-based device.

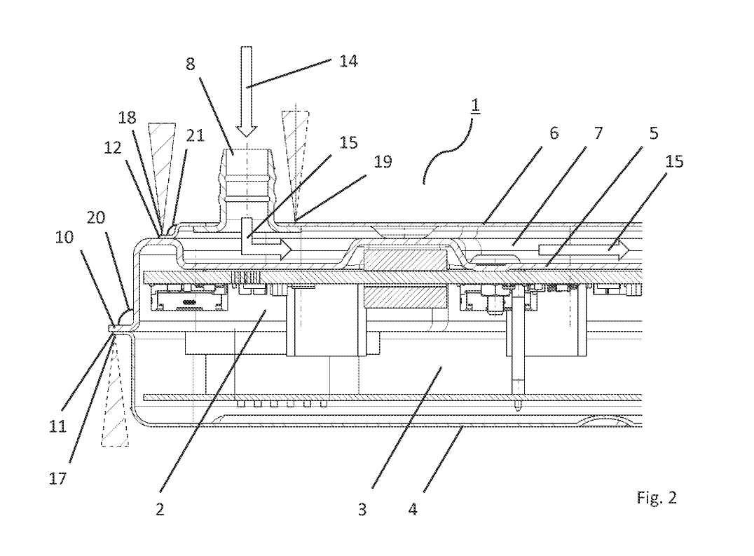

The device is a device 1 for cooling power electronics 2 by means of a cooling medium. The power electronics 2 are arranged in a housing 3 of the device (see FIG. 2).

The device 1 has a housing attachment 6 arranged directly at the housing 3. The housing attachment 6 and the housing 3 form a space 7 (see FIG. 2) for receiving the cooling medium.

The housing attachment The inlet 8 and the outlet 9 are designed in the form of connection pieces.

One arrow 14 shows the flow direction of the cooling medium into the inlet 8. One arrow 16 shows the flow direction of the cooling medium out of the outlet 9.

The housing 3 and the housing attachment 6 consist of 99.5% aluminum or an Al-alloy. The housing 3 and the housing attachment 6 are connected by means of a laser welding process.

In addition, the housing 3 has multiple transport connections 13 for supplying the power electronics 2 with energy.

FIG. 2 shows a detailed schematic view of section A - A through the invention based device shown in FIG. 1.

The power electronics 2 is arranged in the housing 3 of the device 1.

As described above, the device 1 has a housing attachment 6. The housing attachment 6 is directly arranged at the housing 3. The housing attachment 6 and the housing 3 form a space 7 for receiving the cooling medium. The space 7 is designed in the form of a container for liquids.

The space 7 is located between the housing attachment 6 and a top part 5 of the housing 3. An arrow 15 shows the flow direction of the cooling medium in the space 7. According to arrows 14, 15 and 16, the cooling medium flows through the space 7 (see FIG. 1).

The cooling medium absorbs the heat released via the top part of the housing 5, so that through forced convection a cooling effect takes place in the housing 3, where the power electronics 2 are arranged.

The housing 3 has a bottom part 4 and the top part 5.

The bottom part 4 and the top part 5 of the housing were deep-drawn by means of a deep-drawing process. The top part 5 of the housing has a continuous brim 10 in its edge zone. The bottom part of the housing has a brim 11. At the same time, the brim 10 of the top part 5 of the housing has a bending angle 20 of approximately 92°.

The bottom part 4 and the top part 5 of the housing are connected by means of a laser welding process via the brims sin 10, 11 (laser welding region 17).

The housing attachment 6 was also deep-drawn by means of a deep-drawing process. The housing attachment 6 has a brim 12. At the same time, the brim 12 of the housing attachment 6 has a bending angle 21 of approximately 92°.

The top part 5 of the housing 3 and the housing attachment 6 are connected by means of a laser welding process (laser welding region 18). The connection takes place via the brim 12.

The inlet 8 is also attached to the housing attachment 6 by means of a laser welding process (laser welding region 19).

The method for producing the device 1 for cooling the power electronics 2 by means of a cooling medium can be summarized in the following way:

First, the bottom part 4 and the top part 5 of the housing are connected by means of a laser welding process to form the housing 3, wherein the power electronics 2 have already been placed in the housing 3.

Thereafter, the housing 3 is connected with the housing attachment 6, wherein the housing attachment 6 and the housing 3 form the space 7 for receiving the cooling medium, and wherein the housing attachment 6 has the inlet 8 and the outlet 9 to transport the cooling medium into and out of the space 7. At the same time, the inlet (connection piece) 8 and the outlet (connection piece) 9 are attached by means of the laser welding process at the housing attachment 6.

Alternatively, the top part 5 of the housing and the housing attachment 6 can be connected by means of a laser welding process, wherein the housing attachment 6 and the top part 5 of the housing form the space 7 for receiving the cooling medium.

This has the advantage that the component produced by the housing attachment 6 and top part 5 of the housing (=housing), together with the space 7, can then be subjected to a pressure test in order to determine the tightness of the component produced.

Thereafter, the bottom part 4 and the top part 5 of the housing are connected by means of a laser welding process to form one housing 3, wherein the power electronics 2 are arranged in the housing 3. At the same time, the space 7 is located outside the housing 3.

By means of the laser welding process, it is possible to connect in a simple manner the components bottom part and top part of the housing, as well as top part of the housing and housing attachment, which consist 99.5% of aluminum or an Al-alloy.

### REFERENCE LIST

1 device
2 Power electronics
3 housing
4 bottom part of the housing
5 top part of the housing
6 space
7 housing attachment
8 inlet (connection piece)
9 outlet (connection piece)
10 brim
11 brim
12 brim
13 transport connection
14 arrow
15 arrow
16 arrow
17 laser welding region
18 laser welding region
19 laser welding region
20 bending angle
21 bending angle

1. A device for cooling power electronics by means of a cooling medium, comprising:
power electronics arranged in a housing,
a housing attachment which is arranged at the housing in such a way that the housing attachment and the housing form a space for receiving the cooling medium,
wherein the housing has at least one bottom part and one top part, wherein both housing parts are designed to be connected by means of a laser welding process,
wherein the housing attachment and the housing are designed to be connected by means of a laser welding process, and
wherein the housing and the housing attachment consist of aluminum.

2. The device according to claim 1, wherein the housing and the housing attachment consist of an aluminum alloy or of 99.5% aluminum.

3. The device according to claim 1 wherein the bottom part and the top part of the housing are deep-drawn, punched or deep-pressed.

4. The device according to claim 1 wherein the bottom part of the housing has a brim and the top part of the housing has a brim, wherein a connection between both housing components takes place via the brims.

5. The device according to claim 1 wherein the housing attachment is deep-drawn, punched or deep-pressed.

6. The device according to claim 1 wherein the housing attachment has a brim, wherein the housing attachment can be connected to the housing by means of the brim.

7. The device according to claim 1 wherein the housing attachment has at least one inlet and at least one outlet for the cooling medium.

8. The device according to claim 7, characterized wherein the inlet and the outlet can be connected by means of a laser welding process to recesses at the housing attachment.

9. A method for producing a device for cooling power electronics, which comprises the following steps:
Connecting by means of a laser welding process a bottom part and a top part of a housing to form a housing, wherein power electronics are arranged in the housing (3), and
Connecting by means of a laser welding process the housing with a housing attachment, wherein the housing attachment and the housing form a space for receiving a cooling medium, and wherein the housing and the housing attachment consist of aluminum.

10. A method for producing a device for cooling power electronics, which comprises the following steps:
Connecting by means of a laser welding process a top part and a housing attachment of a housing to form a housing, wherein the housing attachment and the top part of the housing form a space for receiving a cooling medium, and
Connecting by means of a laser welding process a bottom part and a top part of a housing to form a housing, wherein power electronics are arranged in the housing, and wherein the housing and the housing attachment consist of aluminum.
